(19) United States
(12) Patent Application Publication
(10) Pub. No.: US 2023/0378165 A1
(43) Pub. Date: Nov. 23, 2023

(54) Electrostatic Discharge Protection Device Having Multiple Pairs of PN Stripes and Methods of Fabrication Thereof

(71) Applicant: Coolstar Technology, Inc., Santa Clara, CA (US)

(72) Inventors: Zihao M. Gao, Gilbert, AZ (US); Xiaowei Ren, Plano, TX (US)

(21) Appl. No.: 17/750,722

(22) Filed: May 23, 2022

(51) Int. Cl. H01L 27/02

(52) U.S. Cl. CPC H01L 27/0277; H01L 27/0262

(57) ABSTRACT

An ESD protection device includes a deep well having a first conductivity type, a well having the first conductivity type disposed in at least a portion of the deep well, proximate an upper surface of the deep well, and a drain region having a second conductivity type disposed in a portion of the deep well, proximate the upper surface of the deep well. A source structure is disposed in a portion of the well, proximate an upper surface of the well and spaced laterally from the drain region. The source structure includes multiple pairs of stripe regions, each of the stripe regions including a doped region of the first conductivity type and a doped region of the second conductivity type disposed laterally adjacent to one another. A gate is disposed over the well, between the drain region and the source structure, the gate being electrically isolated from the well.

### BACKGROUND

The present invention relates generally to the electrical, electronic and computer arts, and, more particularly, to electrostatic discharge protection devices and fabrication methods.

Electrostatic discharge (ESD) is often recognized as one of the biggest threats to sensitive electronic devices, such as mobile phones, etc. An ESD event generally involves charge transfer between a device and an external body due to electrostatic potential difference. During an ESD event, large currents can pass through the pins of an integrated circuit (IC) for very short durations of time causing electrical and thermal overstress and resulting internal damage. Such internal damage can wholly or partly impair the functionality of the device or its operational lifetime. ESD sensitivity testing is in wide use for quantifying susceptibility of devices to damage in various environments. Such tests emulate ESD events in a controlled fashion by subjecting the device under test to transient electrical overstress for various discharge pathways. Hence, building ESD protection into electronic devices and establishing its efficacy through sensitivity testing has become a routine part of the product development process.

For ESD protection of IC devices, various protection elements are added to augment core circuitry in the device. A widely used method of ESD protection employs a power clamp coupled between positive and negative voltage supply nodes in combination with individual protection elements to provide bidirectional current discharge paths between each of the pins and one or more of the voltage supply nodes. A discharge path in effect diverts large discharge currents away from vulnerable internal circuitry. For this to be effective, the discharge path must be fast acting and be of sufficiently low impedance so that the terminal voltage is limited to a tolerable level during the ESD event.

Power clamps can generally be classified as static or transient according to their manner of operation. A static clamp limits voltage rise by conducting when the terminal voltage exceeds a predetermined level. Such clamps are often set to a threshold level higher than the specified absolute maximum power supply voltage with the addition of an adequate margin to avoid false activation during normal operation. Thus, terminal voltage can reach well in excess of the maximum rated supply voltage during an ESD event, which often limits the utility of static clamps. Further, as in the case of diode-based static clamps, resistive voltage drops from large discharge currents will cause the terminal voltage to reach even higher levels than the threshold, thereby exacerbating the problem.

Alternatively, a transient clamp dynamically turns on during a voltage surge arising from discharge events. A resistor-capacitor (RC) trigger circuit is typically employed for detecting fast transients and in turn switching on a large-sized transistor that bypasses discharge currents. This method is effective in limiting the voltage rise during ESD events to a few volts and is widely adopted in complementary metal-oxide-semiconductor (CMOS) circuits.

In a radio frequency (RF) power amplifier (PA) application, the positive voltage supply (VDD) terminal is vulnerable during RF fast switching/swings against voltage spikes, such as spikes generated from parasitic inductor and/or capacitors. Therefore, ESD devices are often used to protect the terminal to prevent device failure. Unfortunately, however, the use of conventional ESD devices typically increases overall leakage current in the device. Such increased leakage current, particularly from the positive voltage supply terminal, contributes to the total power dissipation in the RF PA, which results in performance degradations in the RF PA and ultimately lowers the overall efficiency of the RF PA (a critical performance parameter), which is undesirable.

### SUMMARY

The present invention, as manifested in one or more embodiments, provides an ESD protection device that advantageously reduces overall leakage current in the device, thereby beneficially enhancing performance (e.g., efficiency), particularly in an RF PA application, among other applications. One or more embodiments of the invention employs an ESD protection device including at least one ground-gate n-type metal-oxide semiconductor (ggNMOS) device having multiple pairs of PN stripes in a source region of the device. This arrangement provides a plurality of distributed parasitic bipolar junction transistors (BJTs) which establish current discharge paths during an ESD event, but exhibit very low leakage current during normal operation of the ESD protection device.

In accordance with an embodiment of the invention, an electrostatic discharge (ESD) protection device includes a deep well having a first conductivity type, a well having the first conductivity type disposed in at least a portion of the deep well, proximate an upper surface of the deep well, and a drain region having a second conductivity type disposed in a portion of the deep well, proximate the upper surface of the deep well, the second conductivity type being opposite in polarity to the first conductivity type. A source structure is disposed in at least a portion of the well, proximate an upper surface of the well and spaced laterally from the drain region. The source structure includes multiple pairs of stripe regions, each of the stripe regions including a doped region of the first conductivity type and a doped region of the second conductivity type disposed laterally adjacent to one another. A gate is disposed over at least a portion of the well, between the drain region and the source structure, the gate being electrically isolated from the well by a dielectric layer disposed between the well and the gate. The doped regions of the first and second conductivity types are electrically coupled together, and the drain region is adapted for connection to an input/output pad to be protected from an ESD event.

In accordance with another embodiment of the invention, a method of fabricating an ESD protection device includes: forming a deep well having a first conductivity type; forming a well having the first conductivity type in at least a portion of the deep well, proximate an upper surface of the deep well; forming a drain region having a second conductivity type in a portion of the deep well, proximate the upper surface of the deep well, the second conductivity type being opposite in polarity to the first conductivity type; forming a source structure in at least a portion of the well, proximate an upper surface of the well and spaced laterally from the drain region, the source structure comprising a plurality of pairs of stripe regions, each of the stripe regions including a doped region of the first conductivity type and a doped region of the second conductivity type disposed laterally adjacent to one another; and forming a gate over at least a portion of the well, between the drain region and the source structure, the gate being electrically isolated from the well by a dielectric layer formed between the well and the gate. The doped regions of the first and second conductivity types in the plurality of pairs of stripe regions are electrically coupled together, and the drain region is adapted for connection to an input/output pad to be protected from an ESD event.

Techniques of the present invention can provide substantial beneficial technical effects. By way of example only and without limitation, an ESD protection device according to one or more embodiments of the invention may provide one or more of the following advantages:
lower leakage current;
maintains or enhances efficiency, particularly when used in a power amplifier application;
provides an ability to optimize leakage current and hold voltage to meet prescribed design criteria;
provides one or more variables for controlling an ESD design window (e.g., distance, d, variable shown in FIG. 2A).

These and other features and advantages of the present invention will become apparent from the following detailed description of illustrative embodiments thereof, which is to be read in connection with the accompanying drawings.

### BRIEF DESCRIPTION OF THE DRAWINGS

The patent or patent application file contains at least one drawing executed in color. Copies of this patent application or patent application publication with color drawing(s) will be provided by the U.S. Patent and Trademark Office upon request and payment of the necessary fee.

Non-limiting and non-exhaustive embodiments of the present invention will be described with reference to the following drawings which are presented by way of example only, wherein like reference numerals (when used) indicate corresponding elements throughout the several views unless otherwise specified, and wherein:

FIG. 1 is a cross-sectional view depicting at least a portion of a standard ESD protection device including a grounded-gate n-type metal-oxide semiconductor (ggNMOS) transistor;

FIGS. 2A and 2B are cross-sectional views depicting at least a portion of an exemplary ESD protection device including a ggNMOS transistor having multiple pairs of PN stripes, according to one or more embodiments of the present invention;

FIG. 2C is a top plan view depicting at least a portion of the exemplary ESD protection device shown in FIG. 2A, according to one or more embodiments of the present invention;

FIG. 3 is schematic diagram depicting at least a portion of a simplified equivalent circuit showing parasitic BJTs associated with corresponding pairs of PN stripes in the illustrative ESD protection device shown in FIGS. 2A and 2B, according to one or more embodiments of the present invention;

FIGS. 4A, 4B, 5A and 5B are graphs of illustrative current-voltage (I-V) curves conceptually depicting the effect of the number of pairs of PN stripes on leakage current in an ESD protection device (e.g., consistent with the exemplary ESD protection device shown in FIG. 2A), according to one or more embodiments of the present invention;

FIGS. 6A, 6B, 7A and 7B are graphs of illustrative I-V curves conceptually depicting the impact of the lengths (L_{S} and L_{P}) of the PN stripes on leakage current in an exemplary ESD protection device (e.g., consistent with the illustrative ESD protection device shown in FIG. 2A), according to one or more embodiments of the present invention;

FIGS. 8A-8C are cross-sectional views depicting three different configurations of PN striping in an exemplary ESD protection device (e.g., consistent with the illustrative ESD protection device shown in FIG. 2A), according to embodiments of the present invention;

FIGS. 9, 10A and 10B are graphs of illustrative I-V curves conceptually depicting the impact of the number of pairs of PN stripes on leakage current in an exemplary ESD protection device (e.g., consistent with the illustrative ESD protection device shown in FIG. 2A), while keeping the total length of the combination of equal-sized PN stripes constant, according to one or more embodiments of the invention;

FIGS. 11A-11C are graphs of illustrative I-V curves conceptually depicting the impact of the distance, d, between an edge of the drain region and an adjacent edge of the gate on leakage current in an exemplary ESD protection device (e.g., consistent with the illustrative ESD protection device shown in FIG. 2A), according to one or more embodiments of the present invention; and

FIG. 12 is a block diagram depicting at least a portion of intermediate steps in an exemplary method for fabricating an ESD protection device, consistent with the device shown in FIG. 2A, according to one or more embodiments of the present invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of the present invention, as manifested in one or more embodiments, will be described herein in the context of an illustrative electrostatic discharge (ESD) protection device, and methods for fabricating an ESD protection device, having multiple pairs of PN stripes. The ESD protection device according to embodiments of the invention is well-suited for power applications, such as, for example, a radio frequency (RF) power amplifier (PA) application, among other beneficial uses. It is to be appreciated, however, that the invention is not limited to the specific device(s) and/or method(s) illustratively shown and described herein. Rather, it will become apparent to those skilled in the art given the teachings herein that numerous modifications can be made to the embodiments shown that are within the scope of the claimed invention. That is, no limitations with respect to the embodiments shown and described herein are intended or should be inferred.

For the purpose of describing and claiming embodiments of the invention, the term MISFET, as may be used herein, is intended to be construed broadly and to encompass any type of metal-insulator semiconductor field-effect transistor. The term MISFET is, for example, intended to encompass semiconductor field-effect transistors that utilize an oxide material as their gate dielectric (i.e., metal-oxide semiconductor field-effect transistors (MOSFETs)), as well as those that do not. In addition, despite a reference to the term “metal” in the acronyms MISFET and MOSFET, the terms MISFET and MOSFET are also intended to encompass semiconductor field-effect transistors wherein the gate is formed from a non-metal material such as, for instance, polysilicon; the terms “MISFET” and “MOSFET” are used interchangeably herein.

Although the overall fabrication method and structures formed thereby are entirely novel, certain individual processing steps required to implement a portion or portions of the method(s) according to one or more embodiments of the invention may utilize conventional semiconductor fabrication techniques and conventional semiconductor fabrication tooling. These techniques and tooling will already be familiar to those having ordinary skill in the relevant arts. Moreover, many of the processing steps and tooling used to fabricate semiconductor devices are also described in a number of readily available publications, including, for example: P. H. Holloway et al., Handbook of Compound Semiconductors: Growth, Processing, Characterization, and Devices, Cambridge University Press, 2008; and R. K. Willardson et al., Processing and Properties of Compound Semiconductors, Academic Press, 2001, which are incorporated by reference herein in their entireties. It is emphasized that while some individual processing steps are set forth herein, those steps are merely illustrative and one skilled in the art may be familiar with several equally suitable alternatives that would also fall within the scope of the present invention.

It is to be understood that the various layers and/or regions shown in the accompanying figures are not necessarily drawn to scale. Furthermore, one or more semiconductor layers of a type commonly used in such integrated circuit devices may not be explicitly shown in a given figure for economy of description. This does not imply, however, that the semiconductor layer(s) not explicitly shown are omitted in the actual device or structure.

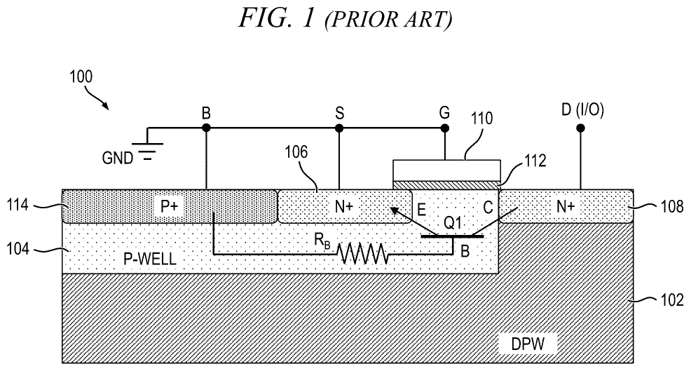

FIG. 1 is a cross-sectional view depicting at least a portion of a standard ESD protection device 100 implemented using a grounded-gate n-type metal-oxide semiconductor (ggNMOS) transistor. Specifically, the ESD protection device 100 includes a deep p-type well (DPW) 102 which serves as a substrate for the device. A p-type well (p-well) 104 is formed partially into the DPW 102 and proximate an upper surface of the DPW. The p-well 104 serves as a body region in the ESD protection device 100. A highly-doped source region 106 of n-type conductivity (N+) is formed in the p-well 104 proximate an upper surface of the p-well. A highly-doped drain region 108, also of n-type conductivity, is formed in the DPW 102 proximate the upper surface of the DPW and laterally adjacent to the p-well 104. The source and drain regions 106, 108 are spaced apart laterally from one another, separated by a p-type body region of the p-well 104.

The ESD protection device 100 includes a gate 110, which may be formed of polysilicon material, disposed above the upper surface of the p-well 104, between the source and drain regions 106, 108. The gate 110 is electrically isolated from the p-well 104 by a thin dielectric layer 112, which is typically formed of an oxide and therefore referred to as a gate oxide layer. As will be known by those skilled in the art, when the gate 110 is more positive relative to the source region 106, it attracts electrons, inducing an n-type conductive channel in the p-well 104 below the gate oxide layer 112, which allows electrons to flow between the n-doped source and drain regions 106, 108 in the ESD protection device 100.

A heavily-doped p-type region (P+) 114 is formed in the p-well 104, proximate the upper surface of the p-well and adjacent to the source region 106. The p-type region 114 can be formed using an implant process. The p-type region 114, which is electrically coupled with the p-well 104, serves as bulk connection in the ESD protection device 100.

In an ESD protection application, gate (G), source (S) and bulk (B) terminals are all connected to ground (GND), as the ggNMOS name implies. A drain (D) terminal of the device 100 is connected to an input/output (I/O) pad under protection. A parasitic NPN bipolar junction transistor (BJT), Q1, is formed, with the n-type drain region 108 serving as a collector (C) of Q1, the p-type body region in the p-well 104 serving as a base (B) of Q1, and the n-type source region 106 serving as an emitter (E) of Q1. A key element to the operation of the ggNMOS transistor as an ESD protection device is a parasitic base resistance, RB, present between the emitter and base terminals of the parasitic NPN BJT Q1. This parasitic resistance RB is a result of the finite conductivity of the p-well 104.

In terms of a basic operation of the ESD protection device 100, when a positive ESD event is present on the I/O pad (drain terminal), the collector-base junction of the parasitic NPN BJT Q1 becomes reverse biased to the point of avalanche breakdown. At this point, the positive current flowing from the base to ground through the parasitic resistance RB induces a voltage potential across RB, thereby causing a positive voltage difference to appear across the base-emitter junction of transistor Q1. When this voltage difference exceeds a prescribed threshold of transistor Q1 (e.g., about 0.7 volt), the base-emitter junction will become forward-biased, triggering the parasitic NPN BJT Q1. With the parasitic NPN BJT Q1 turned on, a current path will be established between the collector and emitter for discharging ESD current in the device 100. In this manner, the ESD protection device 100, particularly in an RF PA application, protects the drain terminal from parasitic voltage spikes.

As previously stated, however, the use of conventional ESD devices typically increases overall leakage current in the circuit. Such increased leakage current, particularly in a power amplifier context, decreases the overall gain and causes performance degradations in the RF PA, which ultimately lowers the overall efficiency of the amplifier. Moreover, the ESD leakage current is generally process, voltage and/or temperature (PVT) dependent, which introduces another source of undesirable variation.

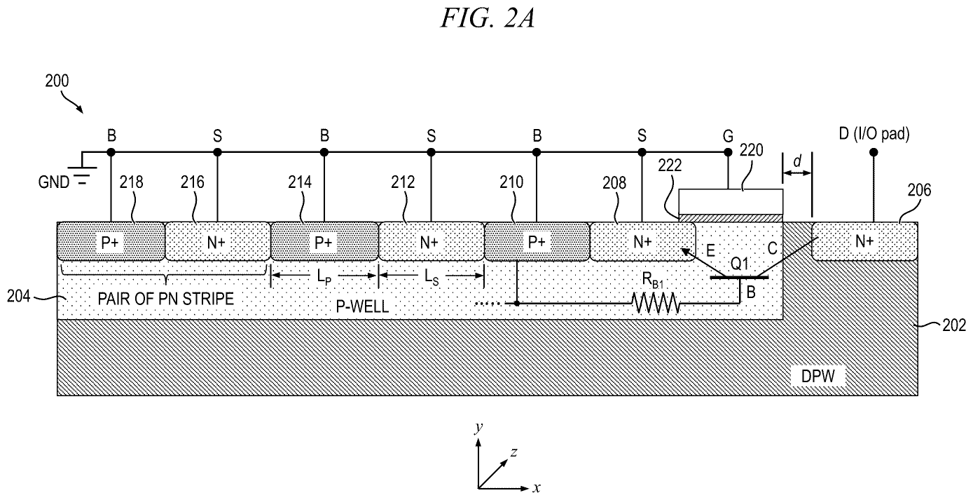

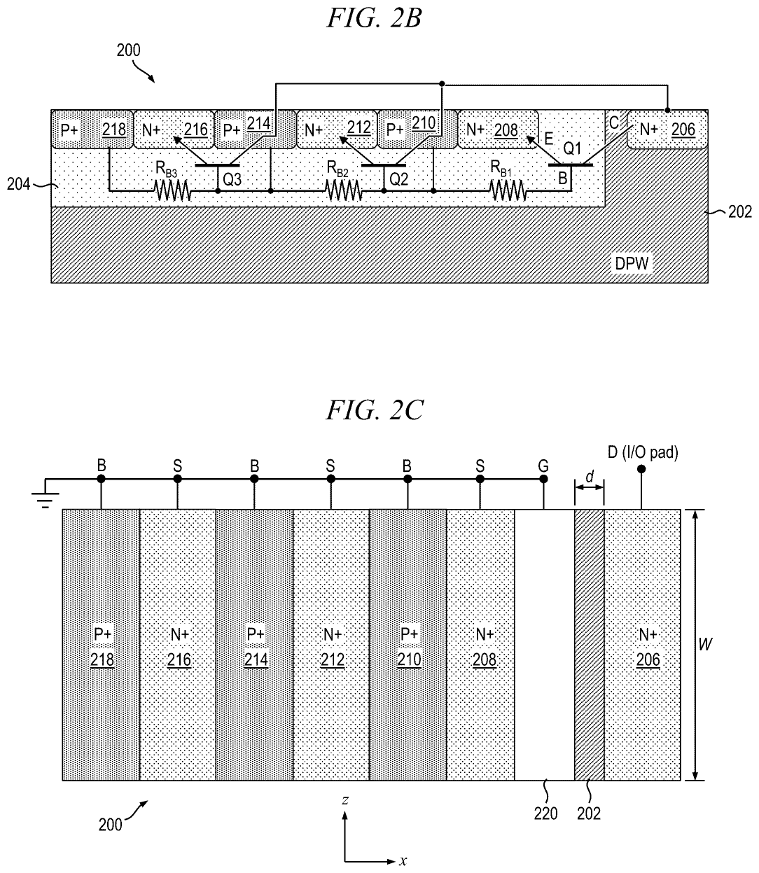

In order to reduce leakage current within a technology platform resulting from the use of ESD protection devices, one or more embodiments of the invention employ an ESD protection device including at least one NMOS transistor device having multiple pairs of PN stripes. FIGS. 2A and 2B are cross-sectional views depicting at least a portion of an exemplary ESD protection device 200 including a metal-oxide semiconductor (MOS) device having multiple pairs of PN stripes in a source region of the device, according to one or more embodiments of the invention. More particularly, with reference to FIG. 2A, the exemplary ESD protection device 200 comprises a deep well, which is preferably a deep well 202 formed in a substrate of the device. The deep well 202 can be formed of single-crystalline silicon (e.g., having a <100> or <111> crystal orientation) that is modified by adding an impurity or dopant (e.g., boron, phosphorous, arsenic, antimony, etc.) of a desired conductivity type (n-type or p-type) and doping level. A p-well may be formed by adding a p-type impurity or dopant (e.g., Group III elements, such as boron) of a prescribed concentration level (e.g., about 10¹⁴ to about 10¹⁸ atoms per cubic centimeter) to the material in which the well resides, such as, for example, by implanting and annealing, to change the conductivity of the material as desired. In other embodiments, an n-type well (n-well) may be formed by adding an n-type impurity or dopant (e.g., Group V elements, such as phosphorus) of a prescribed concentration level to the material.

In this exemplary embodiment, the deep well 202 is of p-type conductivity (e.g., boron dopant) and will thus be referred to as a deep p-well (DPW). A resistivity of the DPW 202 is preferably less than about 1-10 ohms-centimeter (Ω·cm), and a cross-sectional thickness (i.e., depth) of the DPW is about 2 μm, although embodiments of the invention are not limited to any specific resistivity or depth of the DPW. It is to be appreciated that when a grounded-gate p-type metal-oxide semiconductor (ggPMOS) transistor is used as the primary ESD protection device, a deep n-well (DNW) may be employed in place of the DPW 202, as will become apparent to those skilled in the art.

A well 204 is formed in a portion of the DPW 202, proximate an upper surface of the DPW. The well 204 is shallower in depth compared to the DPW 202, such as about 0.5 μm to 1.0 μm, depending on the ESD design parameters. In this illustrative embodiment, the well 204 is preferably a p-type well (e.g., formed by implanting a p-type dopant, such as boron, into a defined portion of the DPW 202, flowed by annealing), and is thus referred to herein as a p-well. A resistivity of the p-well 204 is preferably about 0.05 Ω·cm, although embodiments of the invention are not limited to any specific resistivity.

A highly-doped drain region 206 of n-type conductivity (N+) is formed in the DPW 102 proximate the upper surface of the DPW. The ESD protection device 200 further includes a source structure formed in the p-well 204 proximate an upper surface of the p-well and spaced laterally from the drain region 206. The source structure comprises a plurality of pairs (e.g., three, as in the illustrative ESD protection device 200) of alternating heavily doped n-type (N+) and heavily doped p-type (P+) regions that are laterally adjacent to one another, referred to herein as PN stripes. Each of the doped N+ and P+ regions 208 through 218 forming the pairs of PN stripes are preferably formed by implantation and annealing (to drive in the impurity), in one or more embodiments.

More particularly, the source structure in the illustrative ESD protection device 200 includes a first doped n-type (N+) source region 208, a first doped p-type (P+) body (i.e., bulk) region 210 disposed directly adjacent to the first N+ source region 208, a second doped n-type source region 212 disposed directly adjacent to the first P+ body region 210, a second doped p-type body region 214 disposed directly adjacent to the second N+ source region 212, a third doped n-type source region 216 disposed directly adjacent to the second P+ body region 214, and a third doped p-type body region 218 disposed directly adjacent to the third N+ source region 216. The plurality of alternating N+ source regions 208, 212, 216 and P+ body regions 210, 214, 218 extend from an edge of the gate 220 in a z-direction within the p-well 204. Collectively, the N+ source regions 208, 212 and 216 serve as a distributed source in the NMOS device of the ESD protection device 200. Likewise, the P+ body regions 210, 214 and 218 collectively serve as a distributed body/bulk connection of the NMOS device.

The ESD protection device 200 further includes a gate 220, which may be formed of polysilicon material, disposed above the upper surface of the p-well 204, between the first source region 208 and the drain region 206. The gate 110 is electrically isolated from the p-well 204 by a thin dielectric layer 222, which may be formed of an oxide (e.g., silicon dioxide) and therefore referred to as a gate oxide layer. As will be known by those skilled in the art, when the gate 220 is more positive relative to the source (208, 212, 216) of the NMOS device, it attracts electrons, inducing an n-type conductive channel in the p-well 204 below the gate oxide layer 222, which allows electrons to flow between the n-doped drain region 206 and the n-doped source structure 208, 212, 216 in the ESD protection device 200.

In an ESD protection application, the NMOS device is preferably arranged in a grounded-gate configuration, whereby gate (G), source (S) and body/bulk (B) terminals of the NMOS device are all connected to ground (GND), as the ggNMOS name implies. A drain (D) terminal of the NMOS device in the ESD protection device 200 is connected to an input/output (I/O) pad under protection. With multiple pairs of PN stripes, the NMOS device will form multiple parasitic NPN BJTs, with the n-type drain region 206 serving as a common collector (C) of each parasitic BJT, and the n-type source regions 208, 212, 216 serving as an emitter (E) of the respective parasitic BJTs, as shown in FIG. 2B. The p-well 204 in which the source structure is formed and its extension underneath the gate 220 form bases of the respective parasitic BJTs.

With reference now to FIG. 2B, which conceptually depicts the parasitic BJTs in the exemplary ESD protection device 200 shown in FIG. 2A, a key element to the operation of the ggNMOS transistor as an ESD protection device is a parasitic base resistance, R_{B1}, R_{B2} and R_{B3}, present between the emitter and base of a corresponding parasitic NPN BJT, Q1, Q2 and Q3, respectively.

FIG. 2C is a top plan view depicting at least a portion of the exemplary ESD protection device 200 depicted in FIG. 2A, according to one or more embodiments of the invention. As shown in FIG. 2C, each of the plurality of N+ source regions 208, 212 and 216 and P+ body regions 210, 214 and 218 forming the respective pairs of PN stripes in the ESD protection device 200 is configured having a width, W, that extends laterally in a z-axis direction, parallel to a width W of the gate 220. As the number of pairs of PN stripes increases, an overall length of the source structure in an x-axis direction increases accordingly, in one or more embodiments.

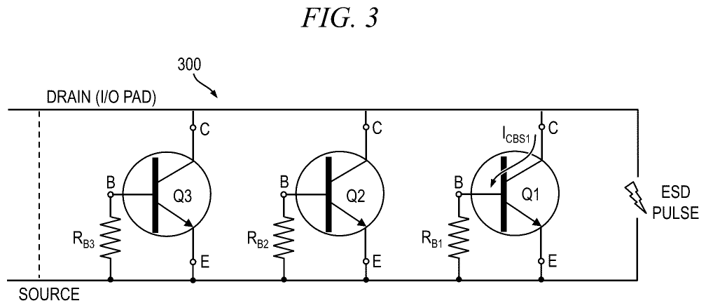

FIG. 3 is schematic diagram depicting at least a portion of a simplified equivalent circuit 300 showing the multiple parasitic BJTs Q1, Q2 and Q3 associated with corresponding pairs of PN stripes in the illustrative ESD protection device 200 shown in FIGS. 2A and 2B, according to one or more embodiments of the present invention. Specifically, the equivalent circuit 300 includes a first parasitic NPN BJT, Q1, having a collector (C) coupled with the drain of the NMOS device and an emitter (E) coupled with the source of the NMOS device. The circuit 300 further includes a second parasitic NPN BJT, Q2, having a collector coupled with the drain of the NMOS device and an emitter coupled with the source of the NMOS device, and a third parasitic NPN BJT, Q3, having a collector coupled with the drain of the NMOS device and an emitter coupled with the source of the NMOS device. Each of the parasitic NPN BJTs Q1, Q2 and Q3 has a base (B) coupled to the source of the NMOS device through a corresponding parasitic base resistance, R_{B1}, R_{B2} and R_{B3}, respectively. The parasitic base resistances R_{B1}, R_{B2} and R_{B3} are a result of the finite conductivity of the p-well 204.

Each parasitic NPN BJT Q1, Q2, Q3 can work independently to divert ESD current during an ESD pulse event, and paralleling each of the parasitic NPN BJTs will enhance the overall capabilities of ESD protection from various sources such as thermal, leakage, etc. During an ESD event, such as when a positive ESD pulse is present on the drain I/O pad, the PN junction between the body and drain regions is reversed-biased to its breakdown avalanche state. An avalanche current, I_{CBS1}, I_{CBS2} and I_{CSS3}, will flow from the collector to the base of each NPN BJT, Q1, Q2 and Q3, respectively, and through the base resistor, R_{B1}, R_{B2} and R_{B3}, to the source, which is grounded.

The avalanche current I_{CBS1}, I_{CBS2} and I_{CSS3} flowing through the respective base resistors R_{B1}, R_{B2} and R_{B3}, respectively, will cause a voltage drop to develop across each of the base resistors. Once this voltage drop across the base resistor exceeds a threshold voltage of the parasitic NPN BJT (e.g., V_{BE}≥0.7 V), snapback will occur in the BJT, wherein the base-emitter junction is in a forward bias state with base current I_{B}; that is, snapback is a mechanism in a BJT in which avalanche breakdown (or impact ionization) generates a sufficient base current to turn on the transistor. At this point, when the parasitic NPN BJT is turned on, a significant collector current, I_{C}, will flow, which is modulated by β·I_{B}, where β is a gain of the parasitic NPN BJT. This collector current I_{C} flowing from the I/O pad (drain) to ground, through the source of the NMOS device, diverts the ESD current and clamps the voltage at the drain terminal, thereby protecting the I/O pad from damage due to the ESD event. This type of ESD protection device is bidirectional; that is, when a negative ESD pulse occurs on the drain I/O pad, the parasitic NPN BJTs are in a forward-bias condition. Thus, the device I/O terminals are again protected from ESD damages.

With reference again to FIG. 2A, each of the N+ source regions 208, 212 and 216 in the NMOS device has a length L_{S} associated therewith. Similarly, each of the P+ body regions 210, 214 and 218 has a length L_{P} associated therewith. The length L_{S} of each of the respective N+ source regions 208, 212, 216 need not be the same; the length L_{P} of each of the respective P+ body regions 210, 214, 218 also need not be same. Although in one or more embodiments, the length L_{S} of the source regions 208, 212, 216 is the same as the length L_{P} of the body regions 210, 214, 218, it is to be appreciated that L_{S} is not necessarily the same as L_{P}. Furthermore, although three pairs of PN stripes are employed in the exemplary ESD protection device 200 of FIG. 2A, embodiments of the invention are not limited to such configuration of the PN stripes. That is, embodiments of the invention are not limited to the specific number of PN stripes or the respective sizes of the N+ source and P+ body regions forming the PN stripes. That being said, it is to be appreciated that in the ESD protection device 200 according to embodiments of the invention, the sizes (L_{S} and L_{P}) and number of pairs of PN stripes, as well as a distance, d, between an edge of the drain region 206 and an edge of the gate 220 facing the drain region, play critical roles in reducing leakage currents and can be optimized, in accordance with aspects of the invention, to beneficially meet a prescribed leakage current requirement and to control one or more other factors, including triggering voltage.

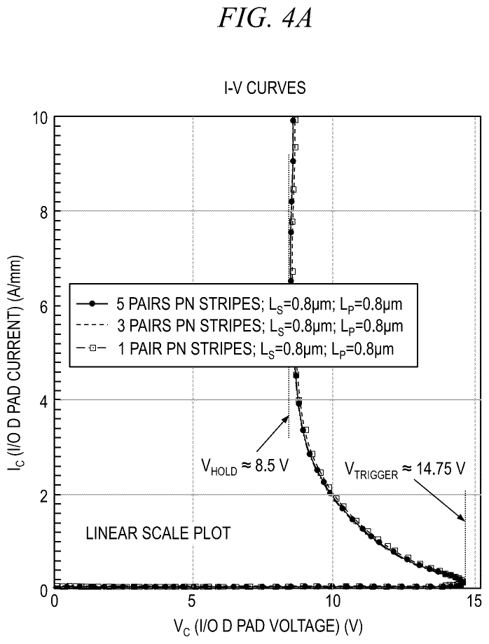

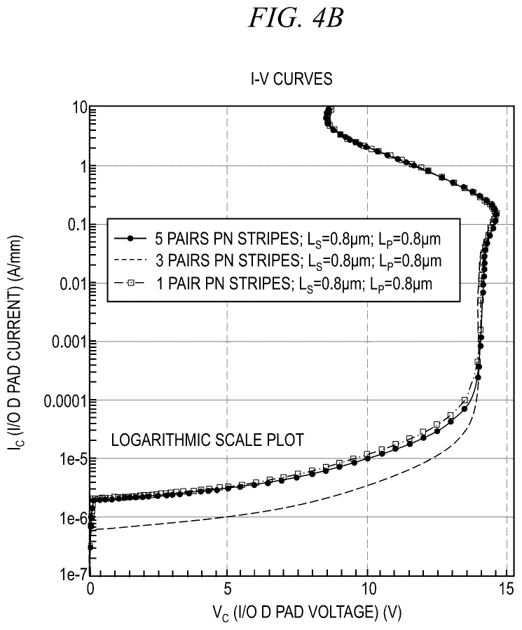

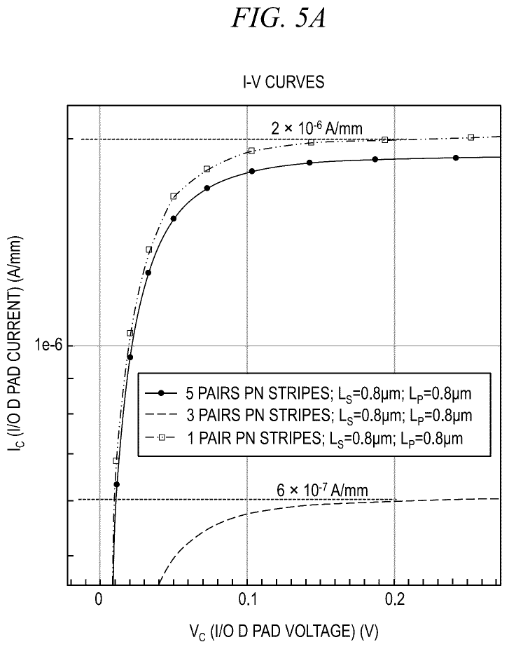

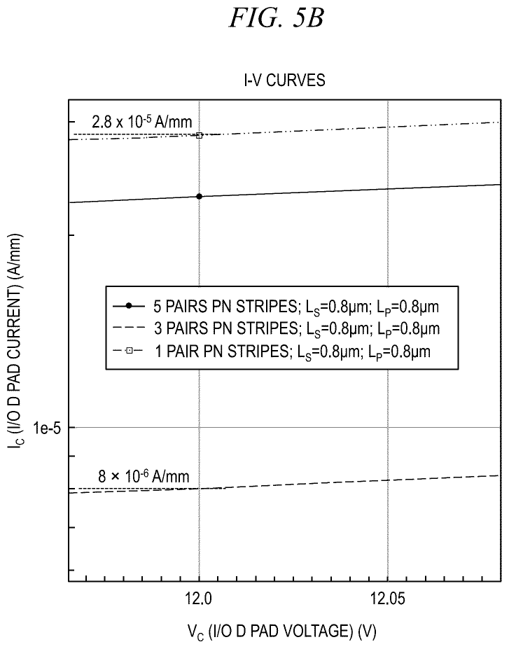

By way of example only and without limitation, FIGS. 4A, 4B, 5A and 5B are graphs of illustrative current-voltage (I-V) curves conceptually depicting the effect of the number of pairs of PN stripes on leakage current in an ESD protection device (e.g., consistent with the exemplary ESD protection device 200 shown in FIG. 2A), according to one or more embodiments of the invention. The x-axis in each of the graphs represents the collector voltage (in volts), V_{C}, of the parasitic BJT in the ESD protection device, measured at the I/O pad (i.e., NMOS drain terminal), and the y-axis represents the collector current (in Amperes per millimeter (A/mm)) in the parasitic BJT. FIGS. 5A and 5B show the I-V curves depicted in FIG. 4B for two different narrow (i.e., zoomed-in) voltage ranges. The curves shown in FIGS. 4A, 5A and 5B were obtained using Synopsis® (a registered trademark of Synopsis, Inc.) TCAD (technology computer-aided design) simulations for a single pair, three pairs and five pairs of PN stripes, with each of the doped P+ body and N+ source regions in the PN stripes having lengths (L_{P} and L_{S}) of 0.8 μm.

In FIG. 4A, the I-V curves are plotted using a linear scale for both the x- and y-axes. The I-V curves depicted in FIG. 4A demonstrate a classic snapback characteristic of the parasitic BJTs using a single pair, three pairs and five pairs of PN stripes. As apparent from FIG. 4A, due to the use of a linear current scale (y-axis), it is difficult to distinguish between the respective I-V curves associated with the different numbers of pairs of PN stripes, particularly when the parasitic BJT is operating in a reverse bias state (prior to snapback); with the range of currents used, the three I-V curves seem to converge and follow substantially the same profile. In this illustration, a triggering voltage, V_{TRIGGER}, which identifies the snapback point at which the parasitic BJT turns on and conducts current in a forward bias state, is about 14.75 volts, and a hold voltage, V_{HOLD}, which identifies the amount of collector voltage (on the I/O pad) required to maintain the parasitic BJT in an active (i.e., forward bias or conducting) state, is about 8.5 volts. It is to be appreciated that although specific values for V_{TRIGGER} and V_{HOLD} are shown in FIG. 4A, these values are merely exemplary and not limiting. In practice, the values for V_{TRIGGER} and V_{HOLD} will be selected based on the particular ESD design window for a prescribed application.

The I-V curves shown in FIGS. 4B, 5A and 5B are plotted using a linear scale for the x-axis and a logarithmic scale for the y-axis. The use of a logarithmic current scale allows the differences between the three different cases of PN stripes to be more evident, particularly the low leakage currents prior to snapback in the parasitic BJT. As apparent from FIG. 4B, using three pairs of PN stripes provides the lowest leakage current, and is therefore optimal for the particular parameters (e.g., stripe length=0.8 μm) used in the ESD protection device. FIG. 5A shows the I-V curves in FIG. 4B plotted for a narrow range of collector voltages V_{C} from zero to about 0.27 volt, and FIG. 5B shows the I-V curves in FIG. 4B plotted for a narrow range of collector voltages V_{C} from about 11.965 volts to about 12.08 volts.

With reference to FIG. 5A, the case with three pairs of PN stripes provides the lowest leakage current, at about 6×10⁻⁷ A/mm, and the single pair of PN stripes provides the highest leakage current, at about 2×10⁻⁶ A/mm, for the range of collector voltage shown. Likewise, FIG. 5B shows that the case with three pairs of PN stripes provides the lowest leakage current, at about 8×10⁻⁶ A/mm, and the single pair of PN stripes provides the highest leakage current, at about 3×10⁻⁵ A/mm, for the range of collector voltages shown. At near zero bias of about 0.2 volt, the leakage current using a single pair of PN stripes is about three times greater than using three pairs of PN stripes, and at about 12 volts, the single pair case is about 3.75 times greater than for three pairs of PN stripes. Thus, it is clear that using multiple pairs of PN stripes—three, in this example—provides optimally reduced leakage current in the ESD protection device.

As an unexpected result, the benefit to using multiple pairs of PN stripes is not necessarily linear. For example, using three pairs of PN stripes in this illustrative embodiment provides lower leakage current than using five pairs of PN stripes (which provides only a marginal reduction in leakage current compared to the single pair case), at least under a prescribed set of device parameters. Furthermore, when stripe lengths for the doped N+ source regions and P+ body regions are not equal to one another (i.e., L_{S}≠L_{P}), simulation data shows larger leakage current compared to using equal stripe lengths (i.e., L_{S}=L_{P}), with all other parameters being the same.

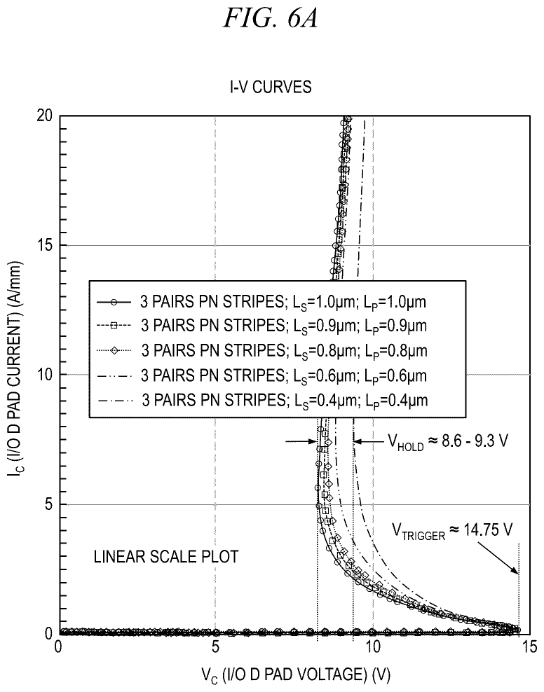

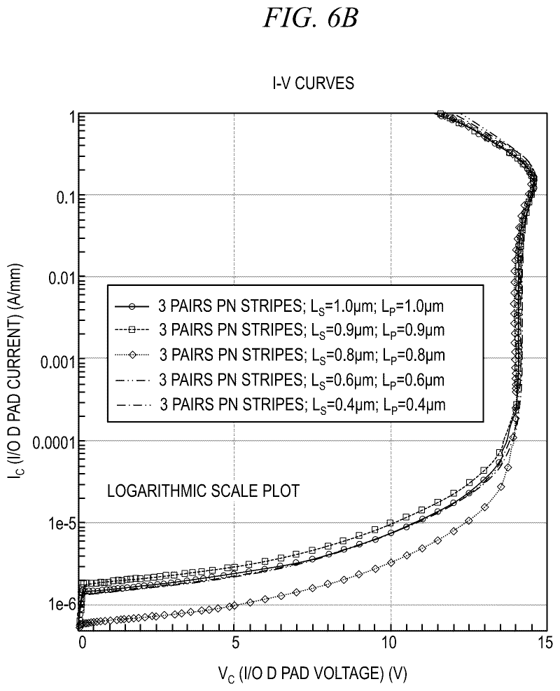

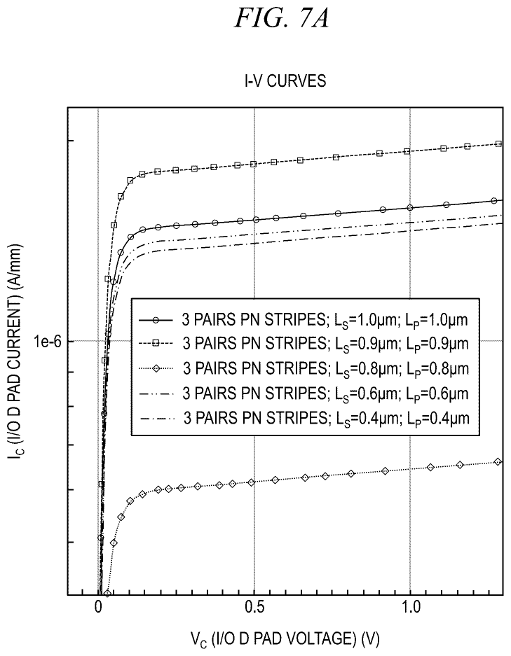

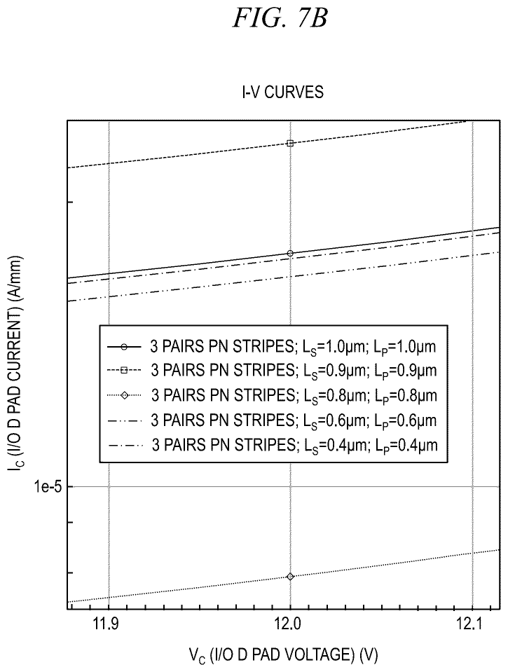

By way of example only and without limitation, FIGS. 6A, 6B, 7A and 7B are graphs of illustrative I-V curves conceptually depicting the impact of the lengths (L_{S} and L_{P}) of the PN stripes on leakage current in an ESD protection device (e.g., consistent with the ESD protection device 200 shown in FIG. 2A), according to one or more embodiments of the invention. The x-axis in each of the graphs represents the collector voltage (in volts), V_{C}, of the parasitic BJT in the ESD protection device, measured at the I/O pad (i.e., NMOS drain terminal), and the y-axis represents the collector current (in A/mm) in the parasitic BJT. FIGS. 7A and 7B show the I-V curves depicted in FIG. 6B for two different narrow (i.e., zoomed-in) voltage ranges. The curves shown in FIGS. 6A through 7B were obtained using Synopsis® TCAD simulations for three pairs of PN stripes, with the doped P+ body and N+ source regions in the PN stripes having lengths (L_{P} and L_{S}) of 0.4 μm, 0.6 μm, 0.8 μm, 0.9 μm and 1.0 μm (with L_{P}=L_{S}).

In FIG. 6A, the I-V curves are plotted using a linear scale for both the x- and y-axes. The I-V curves depicted in FIG. 6A demonstrate a classic snapback characteristic of the parasitic BJTs using three pairs of PN stripes of five different lengths. As apparent from FIG. 6A, due to the use of a linear current scale (y-axis), it is difficult to distinguish between the respective I-V curves associated with the different lengths of PN stripes, particularly when the parasitic BJT is operating in a reverse bias state (prior to snapback); when the parasitic BJT is in reverse bias, the five I-V curves seem virtually the same. In this illustration, a triggering voltage, V_{TRIGGER}, which identifies the snapback point at which the parasitic BJT turns on and conducts current in a forward bias state, is about 14.75 volts, regardless of the length of the PN stripes.

After snapback occurs, when the parasitic BJT is operating in a forward bias state, there is a slightly more pronounced separation between the various I-V curves, evidencing the impact of PN stripe size on hold voltage. In this example, the hold voltage V_{HOLD} varies in a range of about 8.6-9.3 volts, depending on the PN stripe size. As apparent from FIG. 6A, a PN stripe length of 1.0 μm provides the lowest hold voltage, with the hold voltage increasing (seemingly monotonically) with decreasing PN stripe length; a PN stripe length of 0.4 μm provides the highest hold voltage. It is interesting to note that in FIG. 6A, the separation between hold voltages associated with the respective I-V curves becomes less pronounced once the PN stripe length increases to about 0.8 μm or greater.

The I-V curves shown in FIGS. 6B, 7A and 7B are plotted using a linear scale for the x-axis (collector voltage V_{C}) and a logarithmic scale for the y-axis (collector current I_{C}). The use of a logarithmic current scale allows the differences between the five different cases of PN stripe lengths to be more evident, particularly the low leakage currents prior to snapback in the parasitic BJT. With reference to FIG. 6B, using a PN stripe length of 0.8 μm provides the lowest leakage current, and is therefore optimal for the particular parameters (e.g., three pairs of PN stripes) used in the ESD protection device. FIG. 7A shows the I-V curves in FIG. 6B plotted for a narrow range of collector voltages V_{C} from zero to about 1.3 volts, and FIG. 7B shows the I-V curves in FIG. 6B plotted for a narrow range of collector voltages V_{C} from about 11.88 volts to about 12.11 volts.

As apparent from FIG. 7A, for the case with three pairs of PN stripes, a PN stripe length of 0.8 μm provides the lowest leakage current, at about 6.2×10⁻⁷ A/mm, and a PN stripe size of 0.9 μm provides the highest leakage current, at about 1.8×10⁻⁶ A/mm (at a collector voltage of 0.5 V). Likewise, FIG. 7B shows that for the case with three pairs of PN stripes, a PN stripe size of 0.8 μm provides the lowest leakage current, at about 7.9×10⁻⁶ A/mm, and a PN stripe size of 0.9 μm provides the highest leakage current, at about 2.3×10⁻⁵ A/mm (at collector voltage of 12 V). At a collector bias of either about 0.2 volt or about 12 volts, the leakage current using a PN stripe length of 0.9 μm is about 2.9 times greater than using a PN stripe length of 0.8 μm.

As an unexpected result in this example scenario, leakage current in the ESD protection device does not appear to vary linearly or monotonically with PN stripe length. For example, using three pairs of PN stripes, although a PN stripe length of 0.9 μm provides the highest leakage current, the next highest leakage current is obtained using a PN stripe length of 1.0 μm, followed by PN stripe lengths of 0.6 μm, 0.4 μm, and 0.8 μm (in order of decreasing leakage current), with 0.8 μm providing the lowest leakage current among the PN stripes sizes used in the simulations. This observation shows that leakage currents are a more complicated function of the two variables; number of pairs of PN stripes and sizes of PN stripes, among other parameters. Using unequal N+ and P+ stripe lengths (L_{S}, L_{P}) would introduce additional complexity into the leakage current optimization function.

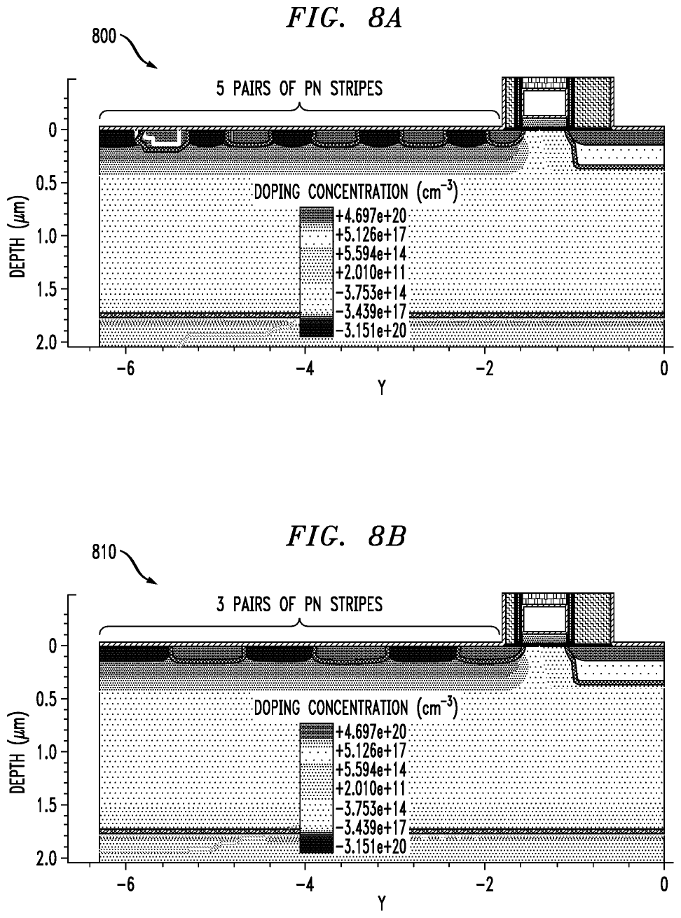

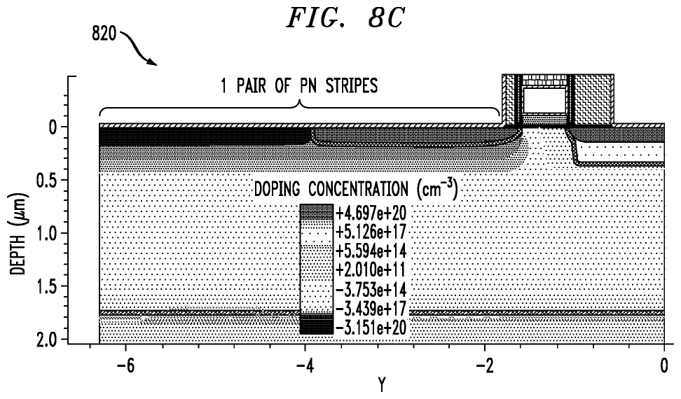

FIGS. 8A-8C are cross-sectional views depicting three different configurations of PN striping in an exemplary ESD protection device, consistent with the ESD protection device 200 shown in FIG. 2A, according to embodiments of the invention. In each of the configurations of the ESD protection device, the total length of the combination of equal-sized PN stripes is held constant, so that as the number of pairs of PN stripes in the ESD protection device is increased, the lengths (L_{S} and L_{P}) of each of the N+ source and P+ body regions decreases accordingly to fit within the same fixed space.

For example, the ESD protection device 800 shown in FIG. 8A uses five pairs of PN stripes, the ESD protection device 810 shown in FIG. 8B uses three pairs of PN stripes, and the ESD protection device 820 shown in FIG. 8C uses one pair of PN stripes. Assuming a total lateral length of the combined PN stripes to be constant at 4.8 μm for each of the PN striping scenarios, and assuming equal size N+ source regions (L_{S}) and P+ body regions (L_{P}), L_{S}=0.48 μm and L_{P}=0.48 μm for each of the five pairs of PN stripes in the ESD protection device 800 of FIG. 8A, L_{S}=0.8 μm and L_{P}=0.8 μm for each of the three pairs of PN stripes in the ESD protection device 810 of FIG. 8B, and L_{S}=2.4 μm and L_{P}=2.4 μm for the single pair of PN stripes in the ESD protection device 820 of FIG. 8C.

The color gradations in FIGS. 8A-8C represent different illustrative doping concentrations in units of number of atoms/cm³. Color gradations are used for different purposes, such as threshold voltage (Vₜₕ) adjustment for MOSFETs used in PAs, breakdown voltage (BV_{DSS}) controls of MOSFETs, etc. Furthermore, the red structures represent n-type doped regions (“+” in doping concentration labels) and the blue structures represent p-type doped regions (“−” in doping concentration labels).

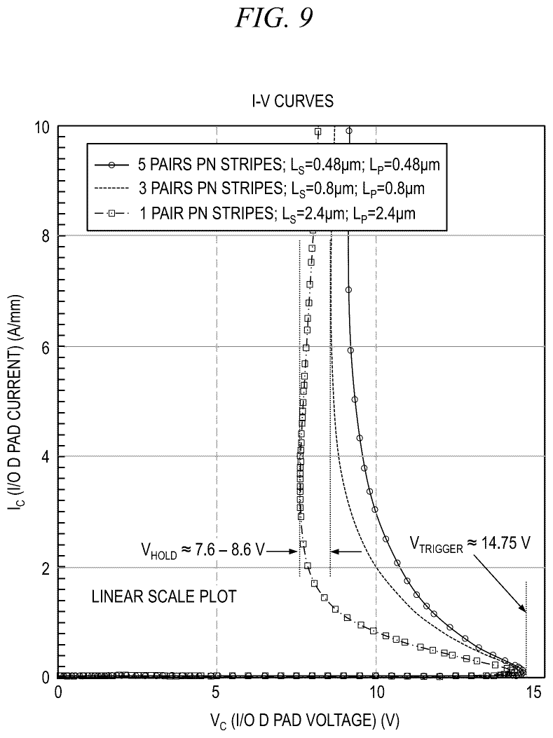

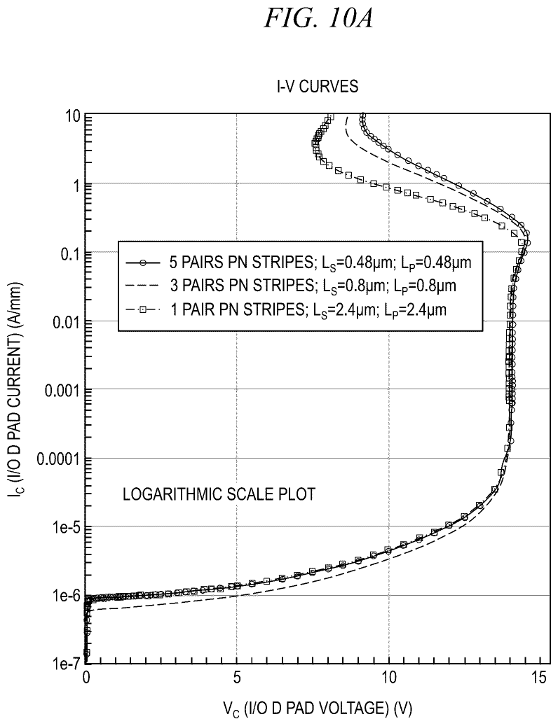

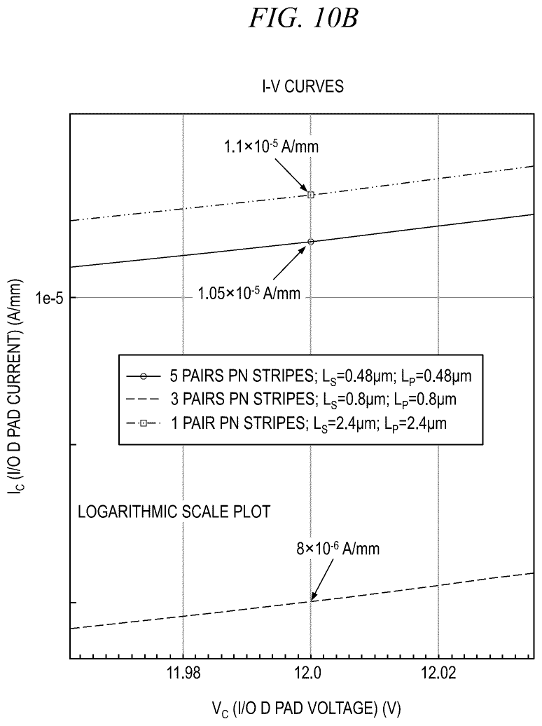

By way of example only and without limitation, FIGS. 9, 10A and 10B are graphs of illustrative I-V curves conceptually depicting the impact of the number of pairs of PN stripes on leakage current in an ESD protection device (e.g., consistent with the ESD protection device 200 shown in FIG. 2A), while keeping the total length of the combination of equal-sized PN stripes constant, according to one or more embodiments of the invention. Hence, given a fixed total length of the source region, the lengths (L_{S}, L_{P}) of the respective PN stripes are adjusted accordingly to accommodate the desired number of pairs of equal-length P+ body and N+ source regions.

The x-axis in each of the graphs represents the collector voltage (in volts), V_{C}, of the parasitic BJT in the ESD protection device, measured at the I/O pad (i.e., NMOS drain terminal), and the y-axis represents the collector current (in A/mm) in the parasitic BJT; the y-axis is linear in FIG. 9 and logarithmic in FIGS. 10A and 10B. FIG. 10B shows the I-V curves depicted in FIG. 10A for a specific narrow (i.e., zoomed-in) voltage range of about 11.962-12.035 V. The curves shown in FIGS. 9, 10A and 10B were obtained using Synopsis® TCAD simulations for five pairs of PN stripes, with the doped P+ body and N+ source regions in the PN stripes having equal lengths (L_{P} and L_{S}) of 0.48 μm, three pairs of PN stripes, with the doped P+ body and N+ source regions in the PN stripes having equal lengths of 0.8 μm, and a single pair of PN stripes, with the doped P+ body and N+ source regions in the PN stripes having equal lengths of 2.4 μm; the total length of the source region in this exemplary scenario is 4.8 μm.

In FIG. 9, the I-V curves are plotted using a linear scale for both the x- and y-axes. The I-V curves depicted in FIG. 9 demonstrate a classic snapback characteristic of the parasitic BJTs using five pairs, three pairs and one pair of PN stripes of different respective lengths. As apparent from FIG. 9, due to the use of a linear current scale (y-axis), it is difficult to distinguish between the respective I-V curves associated with the different lengths of PN stripes when the parasitic BJT is operating in a reverse bias state (prior to snapback); when the parasitic BJT is in reverse bias, the I-V curves seem virtually the same. In this illustration, a triggering voltage, V TRIGGER, which identifies the snapback point at which the parasitic BJT turns on and conducts current in a forward bias state, is about 14.75 volts, regardless of the length or number of pairs of the PN stripes.

After snapback occurs, when the parasitic BJT is operating in a forward bias state, there is a more pronounced separation between the various I-V curves, evidencing the impact of PN stripe size and/or number of pairs of PN stripes on hold voltage. In this example, the hold voltage V_{HOLD} varies in a range of about 7.6 to 8.6 volts, depending on the number of pairs of PN stripes and PN stripe size. As apparent from FIG. 9, for a fixed total length of the source region of 4.8 μm, the lowest hold voltage is achieved using a single pair of PN stripes, with the hold voltage increasing (seemingly monotonically) with an increasing number of pairs of PN stripes. Thus, there is a tradeoff that exists between reducing leakage current and reducing hold voltage in the ESD protection device.

The I-V curves shown in FIGS. 10A and 10B are plotted using a linear scale for the x-axis (collector voltage V_{C}) and a logarithmic scale for the y-axis (collector current I_{C}). The use of a logarithmic current scale allows the differences between the five different cases of PN stripe lengths to be more evident, particularly the low leakage currents prior to snapback in the parasitic BJT. With reference to FIG. 10A, using three pairs of PN stripes (with L_{S}=L_{P}=0.8 μm) provides the lowest leakage current, and is therefore optimal for the particular parameters (e.g., total length of PN stripes of 4.8 μm) used in the ESD protection device. FIG. 10B shows the I-V curves in FIG. 10A plotted for a narrow range of collector voltages V_{C} from about 11.962-12.035 volts.

As apparent from FIG. 10B, using three pairs of PN stripes provides the lowest leakage current, at about 8.0×10⁻⁶ A/mm, and a single pair of PN stripes provides the highest leakage current, at about 1.1×10⁻⁵ A/mm (at a collector voltage of about 12.0 V). Under these exemplary parameters, the leakage current using three pairs of PN stripes (L_{S}=L_{P}=0.8 μm) is about 27.3 percent lower than using a single pair of PN stripes (L_{S}=L_{P}=2.4 μm) in the ESD protection device, and about 23.8 percent lower than using five pairs of PN stripes (L_{S}=L_{P}=0.48 μm).

As an unexpected result in this example scenario, leakage current in the ESD protection device does not seem to vary linearly or monotonically with the number of pairs of PN stripes, given a fixed total length of PN stripes of 4.8 μm. For example, as stated above, using three pairs of PN stripes provides the lowest leakage current, but the next lowest leakage current is achieved using a single pair of PN stripes, with the highest leakage current exhibited using five pairs of PN stripes among the PN stripes sizes used in the simulations. Again, this observation shows that leakage current optimization is a more complicated function involving more than just two variables; number of pairs of PN stripes and sizes of PN stripes.

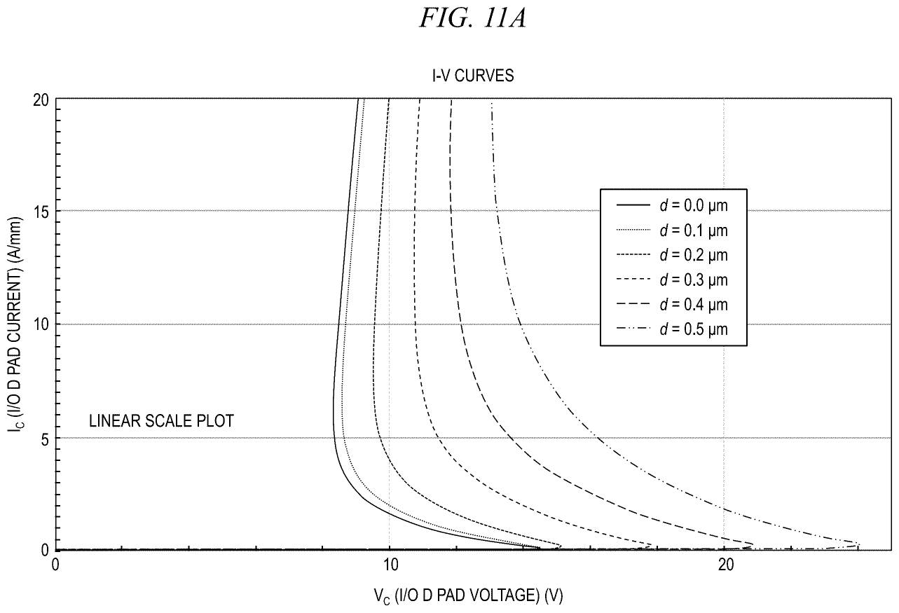

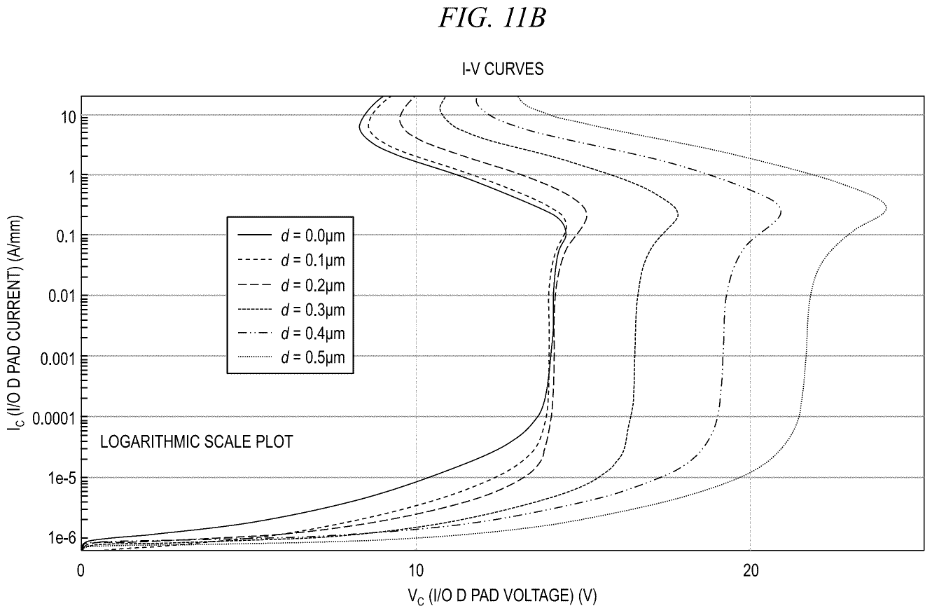

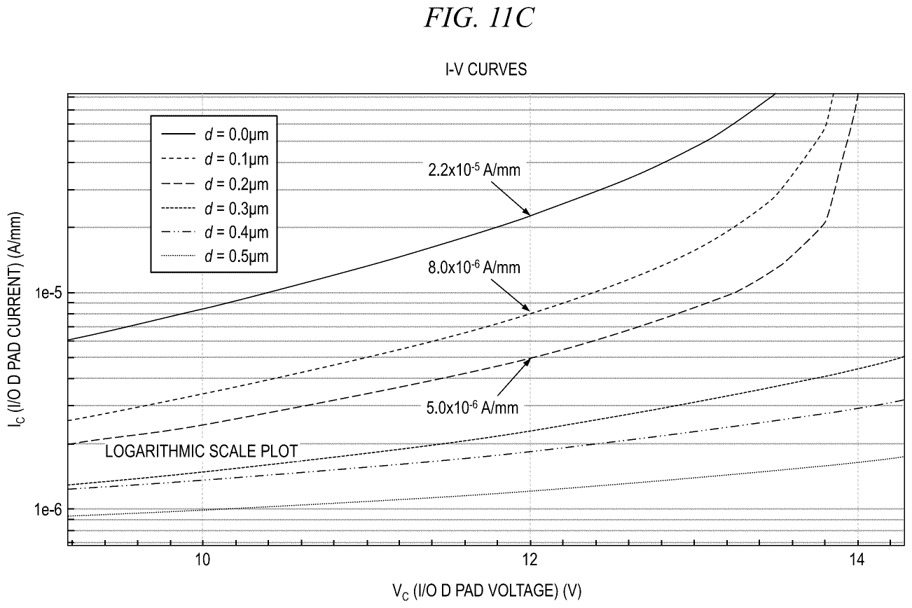

Another factor that can impact leakage current in the ESD protection device is the distance, d, between the edge of the drain region (e.g., drain region 206 shown in FIG. 2A) and a facing edge of the gate (e.g., gate 220 shown in FIG. 2A). By way of example only and without limitation, FIGS. 11A-11C are graphs of illustrative I-V curves conceptually depicting the impact of the distance d between an edge of the drain region and an adjacent edge of the gate on leakage current in an ESD protection device (e.g., consistent with the ESD protection device 200 shown in FIG. 2A), according to one or more embodiments of the invention. Specifically, The x-axis in each of the graphs in FIGS. 11A-11C represents the collector voltage (in volts), V_{C}, of the parasitic BJT in the ESD protection device, measured at the I/O pad (i.e., NMOS drain terminal), and the y-axis represents the collector current (in A/mm) in the parasitic BJT.

The curves shown in FIGS. 11A-11C were obtained using Synopsis® TCAD simulations for six different distance values d varying from 0.0 μm (i.e., no gap) to 0.5 μm, and keeping other parameters the same; all cases use three pairs of PN stripes, doped P+ body and N+ source regions lengths (L_{P}, L_{S}) of 0.8 μm, and a gate length, L_{G}, of 0.5 μm. FIG. 11A uses a linear scale for the y-axis (collector current I_{C}), and FIGS. 11B and 11C employ a logarithmic scale for the y-axis; FIG. 11C shows the I-V curves in FIG. 11B plotted for a narrow range of collector voltages V_{C} from about 9.2-14.2 volts.

The impact of gate to drain distance d on hold voltage in the ESD protection device after snapback occurs is evident and appears to exhibit a fairly linear relationship. With reference to FIG. 11A, the lowest hold voltage—about 8.5 volts—is achieved when there is no gap between the edge of the drain region and the edge of the gate (i.e., d=0.0 μm). The hold voltage increases essentially monotonically as the distance between the drain region and gate edges increases, with the highest hold voltage—about 13 volts—being associated with a distance d of 0.5 μm.

FIG. 11A also clearly shows the impact of drain region edge to gate edge separation distance don triggering voltage. As apparent from FIG. 11A, for both the d=0 μm and d=0.1 μm cases, the triggering voltage is nearly the same at about 14.5 volts, in this illustrative embodiment. For d=0.2 μm, the triggering voltage is about 15 volts. For distances between the drain region edge and gate edge greater than 0.2 μm, the triggering voltage scales essentially linearly at about 3 volts per 0.1 μm; for d=0.3 μm, the triggering voltage is about 17.8 volts, for d=0.4 μm, the triggering voltage is about 21 volts, and for d=0.5 μm, the triggering voltage is about 24 volts.

In FIGS. 11B and 11C, the use of a logarithmic scale for the collector current provides a clearer indication of leakage current in a lower range of collector voltages, prior to snapback. As apparent from FIGS. 11B and 11C, the lowest leakage current is achieved using a distance d of 0.5 μm between facing drain and gate edges. Leakage current increases monotonically with decreasing drain edge to gate edge distance d, with the case d=0.0 μm exhibiting the highest leakage current. As previously stated, FIG. 11C shows the I-V curves in FIG. 11B plotted for a narrow range of collector voltages V_{C}. At a collector voltage V_{C} of 12.0 volts, the leakage current I_{C} with no gap between the drain and gate edges (i.e., d=0.0 μm) is about 2.2×10⁻⁵ A/mm, while at a distance d=0.1 μm, the leakage current is about 8.0×10⁻⁶ A/mm, and at a distance d=0.2 μm, the leakage current is about 5.0×10⁻⁶ A/mm. It is also evident from FIG. 11B that for drain region edge to gate edge distances of about d=0.2 μm or less, the triggering voltage is substantially the same. Consequently, in this illustrative scenario, the case d=0.2 μm provides an optimal tradeoff between lower triggering voltage and reduced leakage current, using these exemplary parameters (e.g., using three pairs of PN stripes of equal lengths L_{S}=L_{P}=0.8 μm, and a gate length L_{G}=0.5 μm).

Although not explicitly shown in the figures, simulation scenarios varying gate length L_{G} while keeping the other parameters constant (e.g., using three pairs of PN stripes of equal lengths L_{S}=L_{P}=0.8 μm, and drain region edge to gate edge distance d held constant at 0.1 μm for all noted simulations) demonstrate that gate length has far less impact on triggering voltage of the ESD protection device than drain region edge to gate edge distance d. Thus, the drain region edge to gate edge distance d is a more effective parameter to modulate the triggering voltage than gate length L_{G}, which makes high triggering voltage ESD protection devices much easier to fabricate than scaling the gate length alone.

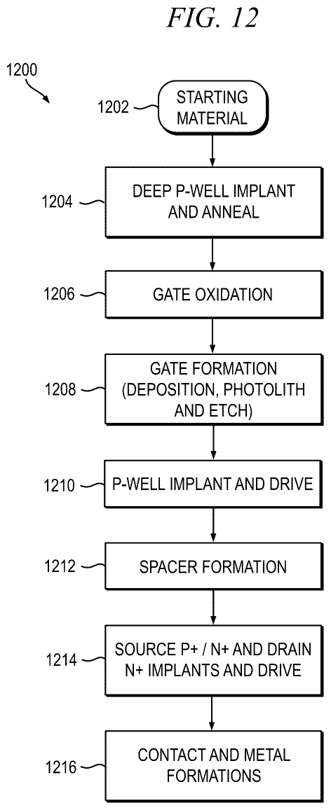

FIG. 12 is a block diagram depicting at least a portion of intermediate process steps in an exemplary method 1200 for fabricating an ESD protection device (e.g., consistent with the illustrative ESD protection device 200 shown in FIG. 2A), according to one or more embodiments of the invention. Referring now to FIG. 12, the method 1200 begins with a starting material in step 1202, such as a semiconductor substrate formed of single-crystalline silicon (e.g., having a <100> or <111> crystal orientation) that is modified by adding an impurity or dopant (e.g., boron, phosphorous, arsenic, antimony, etc.) of a desired conductivity type (n-type or p-type) and doping level. In one or more embodiments, the starting material is a high-resistivity n-type substrate, for example having a resistivity of about 400 Ω·cm, although embodiments of the invention are not limited to any specific resistivity.

In step 1204, a deep p-well implant (e.g., boron) is formed in at least a portion of the n-type substrate, proximate an upper surface of the substrate, followed by annealing to form a deep p-well (DPW). The deep p-well implant is used to form a p-layer above the n-type substrate for isolation purposes, and is preferably formed having a junction depth of about 2 μm, although it is to be appreciated that embodiments of the invention are not limited to any specific junction depth.

A dielectric layer is formed on an upper surface of the substrate in step 1206, such as by using an oxidation process. This dielectric layer, which is preferably an oxide (e.g., silicon dioxide), is subsequently patterned (e.g., using photolithography or the like) and etched to form a gate oxide layer on a portion of an upper surface of the DPW. A gate is then formed on an upper surface of the gate oxide layer, such as by using deposition, photolithography and etching, in step 1208; photolithography and etching are used to define the gate as desired. The gate is preferably formed of polysilicon material, although a gate formed of other materials (e.g., metal) is similarly contemplated by embodiments of the invention.

In step 1210, a p-type well (p-well) region is formed in the DPW, proximate the upper surface of the DPW, using a p-type implant, followed by annealing to drive in the implant. Optionally, if using an ESD device utilizes an NDD region, step 1210 may include an n-type implant followed by annealing to drive in the implant. Although the NDD region is not explicitly shown in the two-dimensional cross-section of the exemplary ESD protection device 200 illustrated in FIG. 2A for economy of description and simplicity, it is to be appreciated that in a full IC process flow, an NDD implant may be included for other purposes. In step 1212, spacers are formed on defined portions of the upper surface of the DPW. The spacers are used to mask subsequent p-type and n-type implants for forming P+ body regions and N+ source regions, respectively, in the ESD protection device.

In step 1214, p-type and n-type implants are used to form the P+ body regions and N+ source regions in the p-well region used in forming multiple pairs of PN stripes in a source side of the ESD protection device. The number of pairs of PN stripes and the lengths of the P+ and N+ regions in the PN stripes are beneficially configured to meet prescribed leakage current, triggering voltage, hold voltage, etc. criteria for the ESD protection device, as previously described. In one or more embodiments, the N+ source and drain regions are formed using an arsenic implant with implant dose of about 5×10¹⁵ atoms/cm² at an energy level of about 40 kiloelectron volts (keV), and the P+ body regions are formed using a boron implant with implant dose of about 3×10¹⁵ atoms/cm² at an energy level of about 15 keV. An anneal is then performed in step 1214 following the P+ and N+ implants to drive the implants a desired depth into the p-well region. Contact and metal connections are formed in step 1216 as part of back-end-of line (BEOL) processing.

At least a portion of the techniques of the present invention may be implemented in an integrated circuit. In forming integrated circuits, identical die are typically fabricated in a repeated pattern on a surface of a semiconductor wafer. Each die includes a device described herein, and may include other structures and/or circuits. The individual die are cut or diced from the wafer, then packaged as an integrated circuit. One skilled in the art would know how to dice wafers and package die to produce integrated circuits. Any of the exemplary structures or circuits illustrated in the accompanying figures, or portions thereof, may be part of an integrated circuit. Integrated circuits so manufactured are considered part of this invention.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from having power MOSFET devices therein formed in accordance with one or more embodiments of the invention, such as, for example, radio frequency (RF) power amplifiers, power management ICs, etc.

An integrated circuit in accordance with aspects of the present disclosure can be employed in essentially any high-frequency, high-power application and/or electronic system, such as, but not limited to, RF power amplifiers, power management ICs, etc. Suitable systems for implementing embodiments of the invention may include, but are not limited to, DC-DC converters, transmitters, communications systems, etc. Systems incorporating such integrated circuits are considered part of this invention. Given the teachings of the present disclosure provided herein, one of ordinary skill in the art will be able to contemplate other implementations and applications of embodiments of the invention.

The illustrations of embodiments of the invention described herein are intended to provide a general understanding of the various embodiments, and they are not intended to serve as a complete description of all the elements and features of apparatus and systems that might make use of the devices, structures and techniques described herein. Many other embodiments will become apparent to those skilled in the art given the teachings herein; other embodiments are utilized and derived therefrom, such that structural and logical substitutions and changes can be made without departing from the scope of this disclosure. The drawings are also merely representational and may not be drawn to scale. Accordingly, the specification and drawings are to be regarded in an illustrative rather than a restrictive sense.

Embodiments of the invention are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

Relational terms such as, for example, “above,” “below,” “upper” and “lower,” may be used herein to indicate a position of elements or structures relative to one another, rather than absolute positioning. Thus, it will become apparent that an upper surface of a given structure, when the structure is flipped upside down, will become a lower surface of the structure, and vice versa.

The corresponding structures, materials, acts, and equivalents of all means or step-plus-function elements in the appended claims are intended to include any structure, material, or act for performing the function in combination with other elements as specifically claimed. The description of the various embodiments has been presented merely for purposes of illustration and description, but is not intended to be exhaustive or limited to only the specific forms disclosed. Many modifications and variations will become apparent to those of ordinary skill in the art given the without departing from the scope and spirit of the invention. The embodiments were chosen and described in order to best explain the principles of the invention and the practical application, and to enable others of ordinary skill in the art to understand the various embodiments with various modifications as are suited to the particular use contemplated.

The abstract is provided to comply with 37 C.F.R. § 1.72(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, inventive subject matter lies in less than all features of a single embodiment. Thus the following claims are hereby incorporated into the Detailed Description, with each claim standing on its own as separately claimed subject matter.

Given the teachings of embodiments of the invention provided herein, one of ordinary skill in the art will be able to contemplate other implementations and applications of the techniques of embodiments of the invention. Although illustrative embodiments of the invention have been described herein with reference to the accompanying drawings, it is to be understood that embodiments of the invention are not limited to those precise embodiments, and that various other changes and modifications can be made therein by one skilled in the art without departing from the scope or spirit of the appended claims.

What is claimed is:

1. An electrostatic discharge (ESD) protection device, comprising:
a deep well having a first conductivity type;
a well having the first conductivity type disposed in at least a portion of the deep well, proximate an upper surface of the deep well;
a drain region having a second conductivity type disposed in a portion of the deep well, proximate the upper surface of the deep well, the second conductivity type being opposite in polarity to the first conductivity type;
a source structure disposed in at least a portion of the well, proximate an upper surface of the well and spaced laterally from the drain region, the source structure comprising a plurality of pairs of stripe regions, each of the stripe regions including a doped region of the first conductivity type and a doped region of the second conductivity type disposed laterally adjacent to one another; and
a gate disposed over at least a portion of the well, between the drain region and the source structure, the gate being electrically isolated from the well by a dielectric layer disposed between the well and the gate;
wherein the doped regions of the first and second conductivity types in the plurality of pairs of stripe regions are electrically coupled together, and wherein the drain region is adapted for connection to an input/output pad to be protected from an ESD event.

2. The ESD protection device according to claim 1, wherein the doped regions of the first and second conductivity types in the plurality of pairs of stripe regions are electrically coupled to ground.

3. The ESD protection device according to claim 2, wherein the doped regions of the first and second conductivity types in the plurality of pairs of stripe regions are electrically coupled to the gate.

4. The ESD protection device according to claim 1, wherein a distance between an edge of the drain region and an edge of the gate facing the drain region is adjusted to modulate a triggering voltage of the ESD protection device.

5. The ESD protection device according to claim 1, wherein a distance between an edge of the drain region and an edge of the gate facing the drain region is configured to minimize leakage current for a prescribed triggering voltage in the ESD protection device.

6. The ESD protection device according to claim 1, wherein a distance between an edge of the drain region and an edge of the gate facing the drain region is equal to or greater than 0.2 μm.

7. The ESD protection device according to claim 1, wherein the source structure in the ESD protection device comprises three pairs of stripe regions.

8. The ESD protection device according to claim 1, wherein a length of each of the doped regions of the first conductivity type is equal to a length of each of the doped regions of the second conductivity type.

9. The ESD protection device according to claim 8, wherein a length of each of the doped regions of the first and second conductivity types is equal to or less than 0.8 μm.

10. The ESD protection device according to claim 1, wherein a length of each of the doped regions of the first conductivity type is different than a length of each of the doped regions of the second conductivity type.

11. The ESD protection device according to claim 1, wherein each of the doped regions of the first and second conductivity types forming the plurality of pairs of stripe regions in the source structure is configured having a width that extends laterally in a direction parallel to a width of the gate.

12. The ESD protection device according to claim 1, wherein the first conductivity type is p-type, and the second conductivity type is n-type.

13. A method for fabricating an electrostatic discharge (ESD) protection device, the method comprising:
forming a deep well having a first conductivity type;
forming a well having the first conductivity type in at least a portion of the deep well, proximate an upper surface of the deep well;
forming a drain region having a second conductivity type in a portion of the deep well, proximate the upper surface of the deep well, the second conductivity type being opposite in polarity to the first conductivity type;
forming a source structure in at least a portion of the well, proximate an upper surface of the well and spaced laterally from the drain region, the source structure comprising a plurality of pairs of stripe regions, each of the stripe regions including a doped region of the first conductivity type and a doped region of the second conductivity type disposed laterally adjacent to one another; and
forming a gate over at least a portion of the well, between the drain region and the source structure, the gate being electrically isolated from the well by a dielectric layer formed between the well and the gate;
wherein the doped regions of the first and second conductivity types in the plurality of pairs of stripe regions are electrically coupled together, and wherein the drain region is adapted for connection to an input/output pad to be protected from an ESD event.

14. The method according to claim 13, further comprising adjusting a distance between an edge of the drain region and an edge of the gate facing the drain region to modulate a triggering voltage of the ESD protection device.

15. The method according to claim 13, further comprising configuring a distance between an edge of the drain region and an edge of the gate facing the drain region to minimize leakage current for a prescribed triggering voltage in the ESD protection device.

16. The method according to claim 13, further comprising configuring a distance between an edge of the drain region and an edge of the gate facing the drain region to be equal to or greater than 0.2 μm.

17. The method according to claim 13, wherein the source structure in the ESD protection device is formed having three pairs of stripe regions.

18. The method according to claim 13, further comprising configuring a length of each of the doped regions of the first conductivity type to be equal to a length of each of the doped regions of the second conductivity type.

19. The method according to claim 18, wherein a length of each of the doped regions of the first and second conductivity types is equal to or less than 0.8 μm.

20. The method according to claim 13, further comprising configuring a length of each of the doped regions of the first conductivity type to be different than a length of each of the doped regions of the second conductivity type.

21. The method according to claim 13, further comprising configuring each of the doped regions of the first and second conductivity types forming the plurality of pairs of stripe regions in the source structure to have a width that extends laterally in a direction parallel to a width of the gate.

22. The method of claim 13, wherein the first conductivity type is p-type, and the second conductivity type is n-type.
